(19) United States
(12) Patent Application Publication
(10) Pub. No.: US 2026/0072362 A1
(43) Pub. Date: Mar. 12, 2026

(54) SENSOR DEVICE FOR A MICROLITHOGRAPHIC PROJECTION EXPOSURE APPARATUS AND METHOD FOR OPERATING A SENSOR DEVICE

(71) Applicant: Carl Zeiss SMT GmbH, Oberkochen (DE)

(72) Inventors: Ulrich SCHOENHOFF, Ulm (DE); Christoph VON CUBE, Aalen (DE)

(21) Appl. No.: 19/388,000

(22) Filed: Nov. 13, 2025

Related U.S. Application Data
(63) Continuation of application No. PCT/EP2024/063667, filed on May 17, 2024.

(30) Foreign Application Priority Data
May 22, 2023 (DE) 10 2023 204 733.0

(51) Int. Cl. G03F 7/00; G01P 15/093; G01P 15/125

(52) U.S. Cl. CPC G03F 7/7085; G01P 15/093; G01P 15/125

(57) ABSTRACT

A sensor device for a microlithographic projection exposure apparatus has a measurement object, at least one sensor assigned to the measurement object, and an evaluation unit. The sensor is in the form of a travel sensor. An auxiliary mass suspended from the measurement object via a resilient element is present as the reference for the sensor. The sensor is configured to capture the distance between the auxiliary mass and the measurement object along a first measurement axis. A method of operating such a sensor device is provided.

### CROSS-REFERENCE TO RELATED APPLICATIONS

The present application is a continuation of, and claims benefit under 35 USC 120 to, international application No. PCT/EP2024/063667, filed May 17, 2024, which claims benefit under 35 USC 119 of German Application No. 10 2023 204 733.0, filed May 22, 2023. The entire disclosure of each of these applications is incorporated by reference herein.

### FIELD

The disclosure relates to a sensor device for a microlithographic projection exposure apparatus, as well as related apparatuses and methods.

### BACKGROUND

Projection exposure apparatuses are used to produce extremely fine structures, such as on semiconductor components or other microstructured component parts. An operating principle of the apparatuses involves the production of extremely fine structures down to the order of nanometres by way of generally reducing imaging of structures on a mask, a so-called reticle, on an element to be structured, a so-called wafer, that is provided with photosensitive material. The minimum dimensions of the structures produced are, in general, directly dependent on the wavelength of the light used. The light is typically shaped for the optimum illumination of the reticle in an illumination optics unit. Recently, light sources having an emission wavelength in the order of a few nanometres, for example between 1 nm and 120 nm, such as on the order of 13.5 nm, have increasingly been used. The described wavelength range is also referred to as the EUV range.

Apart from with the use of systems which operate in the EUV range, the microstructured component parts are also produced using commercially established DUV systems, which have a wavelength of between 100 nm and 300 nm, such as 193 nm. With the general desire to be able to produce smaller and smaller structures, the desired optical correction in the systems has increased further. Throughput is often increased to increase efficiency with each new generation of projection exposure apparatuses in the EUV range or DUV range.

A multiplicity of sensors, such sa acceleration sensors, are used to increase image position accuracy and image quality. These are used, for example, in the illumination device and/or the projection lens of the microlithographic projection exposure apparatus. For example, such sensors are used to actively damp a vibration isolation system of a sensor frame having at least one position sensor. Alternatively or additionally, acceleration sensors can also be used in pilot control to actively damp vibrations of optical elements and frames, such as sensor frames or force frames. Likewise, acceleration sensors can be used to support the position control of the optical elements, for example the mirrors. Acceleration sensors can also be used to reduce line-of-sight errors and thus overlay errors.

In order to help make it possible to position and control the optical elements as accurately as possible, a sensor frame is provided, on which position sensors are mounted. The position sensors are used to measure the position of the optical element relative to the sensor frame. The sensor frame is mechanically decoupled from the environment by a vibration isolation system in order to increase the accuracy of the sensor system. The vibration isolation system decouples the sensor frame from external vibrations, such as ground vibrations, but also internal vibrations, which are produced, for example, by the movements of the wafer stage or the reticle stage. The decoupling is effected by way of a suspension via one or optionally a plurality of springs or air springs optionally on a force frame coupled to the optical element or on a bearing. In order to enable active damping of the vibration isolation system, such as at its resonant frequency, use is made of acceleration sensors that capture the acceleration of the sensor frame. The movement carried out by the sensor frame or an optical element, i.e. the acceleration to be captured, is often very small, usually in the picometre range or in the mm/s² range. The use of conventional acceleration sensors from the prior art, such as piezo-ceramic sensors, is only possible to a very limited extent in this frequency range from 1 Hz to 100 Hz, since they exhibit excessively high noise and thus a poor signal-to-noise ratio.

### SUMMARY

The present disclosure seeks to provide a sensor device and a method for operating a sensor device, which also have an improved signal-to-noise ratio at low frequencies.

The disclosure relates to a sensor device for a microlithographic projection exposure apparatus, having a measurement object, at least one sensor assigned to the measurement object, and an evaluation unit. The sensor is in the form of a travel sensor. An auxiliary mass suspended from the measurement object via a resilient element is present as the reference for the sensor. The sensor is configured to capture the distance between the auxiliary mass and the measurement object along a first measurement axis. The evaluation unit is configured to numerically form the first derivative and/or the second derivative of the distances captured by the travel sensor.

The sensor device involves at least one sensor being in the form of a travel sensor, an auxiliary mass being suspended from the measurement object via a resilient element is present as the reference for the sensor, and the sensor being configured to repeatedly capture the distance between the auxiliary mass and the measurement object along a first measurement axis, that is to say the position of the measurement object with respect to the auxiliary mass. The auxiliary mass can be mechanically decoupled from the measurement object by the resilient element and can serve as a motionless reference for the sensor for measuring the distance or position of the measurement object with respect to the auxiliary mass. The resilient element can act parallel to the first measurement axis. The use of a travel sensor instead of an acceleration sensor can help result in an improved signal-to-noise ratio in a lower measurement frequency range, i.e. in the range between 1 Hz and 100 Hz, and thus more accurate position capture.

According to the disclosure, the evaluation unit can be configured to numerically form the first derivative and/or the second derivative of the distances captured by the travel sensor. For example, it can be desirable for the evaluation unit to be configured to forward the speed or acceleration values generated in this manner to a control unit, wherein the control unit is configured to initiate further measures. Optionally, the control unit can cause actuators to change the position of the measurement object, also periodically. The evaluation unit can also itself be part of a control unit, such as a microcontroller, or can also cause actuators to initiate counterforces, proportional to the determined speed signal, to the movements detected by the travel sensor in order to damp the measurement object, or to reduce or eliminate the influence of disturbance variables.

It can be desirable for the travel sensor to be in the form of an optical encoder. The optical encoder can comprise a scale, which is attached to the auxiliary mass, and a light source, as well as a grating which is attached to that side of the measurement object which is opposite the scale. Optical encoders typically include a beam splitter that splits the light emitted by the light source into two beams. The two beams can be incident on the diffraction grating at two different positions and are diffracted there. The first beam can then be projected onto a first mirror via a quarter-wave plate and the second beam can be projected onto a second mirror via a further quarter-wave plate, where they each can be reflected back onto the diffraction grating, diffracted there and directed back onto the beam splitter. The interference pattern indicated on the scale can change as a result of the movement of the measurement object and thus a change in distance between the measurement object and the auxiliary mass. Alternatively, the travel sensor may also be in the form of a capacitive sensor, wherein a first of the electrodes can be attached to the auxiliary mass and the other of the electrodes can be attached on that side of the measurement object which is opposite the first electrode. In addition, it can be desirable in a further alternative embodiment for the travel sensor is in the form of an interferometer.

In order to help decouple the auxiliary mass from the measurement object, the resilient element of the auxiliary mass can be selected such that the suspension frequency is between 0.1 Hz and 100 Hz, such as between 0.1 Hz and 50 Hz, for example between 1 Hz and 30 Hz.

In order to be able to measure the movement of the measurement object in all six rigid body degrees of freedom, it can be desirable for a second sensor in the form of a travel sensor to be present and is configured to capture the distance between the measurement object and the auxiliary mass along a second measurement axis arranged linearly independently of, for example perpendicular or approximately perpendicular to, the first measurement axis, and/or that a third sensor in the form of a travel sensor is present and is configured to capture the distance between the measurement object and the auxiliary mass along a third measurement axis arranged linearly independently of, for example perpendicular or approximately perpendicular to, the first measurement axis and the second measurement axis. In this context, it can be desirable for a further resilient element to be present on the second measurement axis or parallel to the second measurement axis, and for an additional resilient element to be present on the third measurement axis or parallel to the third measurement axis, from which the auxiliary mass is suspended relative to the measurement object. This can help enable the auxiliary mass to be mechanically decoupled from the measurement object.

The resilient element can be in the form of a leaf spring or a spiral spring. However, more complex geometries of the resilient element are also possible, wherein the resilient element is designed in such a way that a predefined stiffness is specifically realized in the measurement axes and the other axes. Alternatively or additionally, it is also possible for the resilient element to be in the form of a permanent magnetic gravity compensator. For example, two magnetically identically oriented magnets can be arranged at a distance from each other along an axis which can be arranged parallel to the measurement axis. Provided in the central region of this axial magnetic arrangement can be an outer circumferential magnetic ring which at least partially encloses the inner magnets. The outer magnetic ring can have a magnetic orientation transverse to the inner magnets, with the result that the inner pole of the outer magnet is adjacent to a pole of the same name of the first inner magnet and to a pole of a different name of the second inner magnet. This can result in a magnetic force along the longitudinal axis between the inner and outer magnets, which remains almost constant despite a relative displacement of the outer magnet with respect to the inner magnets in a wide range of displacement. This magnetic force can be used as a compensation force and thus decouples the auxiliary mass from the measurement object. Furthermore, it is also possible for the resilient element to be in the form of a combination of a leaf spring or a spiral spring with a permanent magnetic gravity compensator. Alternatively, the resilient element may also be in the form of a plurality of spiral springs and/or leaf springs that are coupled to each other. For example, it can be desirable for the resilient element to be in the form of a gravity compensator in the direction of gravity, while the resilient elements are in the form of springs parallel to the other measurement axes.

Furthermore, it can be desirable for, in addition to the at least one travel sensor, at least one acceleration sensor to be present for capturing the acceleration of the measurement object along a first measurement axis. The at least one acceleration sensor can be in the form of a piezo-ceramic sensor, but other types of acceleration sensors are also possible, such as sensors also in the form of MEMS sensors (Micro-Electro-Mechanical Sensors), for example MOEMS sensors (Micro-Opto-Electro-Mechanical Sensors). For example, it can be desirable for at least one acceleration sensor to be respectively present for each of the three measurement axes, i.e. for the total of three translational degrees of freedom of the measurement object. The acceleration sensor can also be mounted on the measurement object. The movement of the measurement object can be captured both by the acceleration sensor and by the travel sensor.

Since the signal-to-noise ratio for the travel sensor below approximately 100 Hz is generally better than the signal-to-noise ratio of an acceleration sensor and, vice versa, the signal-to-noise ratio for the acceleration sensor above approximately 100 Hz is generally better than for a travel sensor, it can be desirable for a low-pass filter to be assigned to the at least one travel sensor for the purpose of attenuating the captured signal from the travel sensor above a predefined cutoff frequency or a cutoff frequency range, and for a high-pass filter to be assigned to the at least one acceleration sensor for the purpose of attenuating the captured signal below a predefined cutoff frequency or a cutoff frequency range, and for the sum of the transfer function of the signals from the acceleration sensor and the travel sensor to be approximately 1. The cutoff frequency can be approximately in the range of 50 Hz to 500 Hz, such as between 70 Hz and 300 Hz, for example between 100 Hz and 200 Hz. In other words, the measurement data captured by the travel sensor (distances or even once or twice differentiated distances) can be used for smaller movements of the measurement object, which (when Fourier-transformed) are smaller than a cutoff frequency or a cutoff frequency range, and the measurement data captured by the acceleration sensor are used for larger movements of the measurement object, which are greater than a cutoff frequency or a cutoff frequency range. The larger movements which are captured by the travel sensor and are greater than the cutoff frequency or the cutoff frequency range can be damped via the low-pass filter and the smaller movements which are captured by the acceleration sensor and are smaller than the cutoff frequency or the cutoff frequency range can be damped via the high-pass filter.

Within the scope of the disclosure, it can be desirable for the measurement object to be an optical element of the microlithographic projection exposure apparatus, for example a mirror or a lens.

Alternatively or additionally, it can be desirable for the measurement object to be in the form of a sensor frame, wherein the sensor frame has at least one position sensor for the optical element. The sensor frame can be decoupled from the environment via a vibration isolation system, for example via a spring or an air spring. Since, despite the vibration isolation system, for example at the resonant frequency of the vibration isolation system, vibration of the sensor frame can still occur, the distances of the sensor frame along a measurement axis with respect to the auxiliary mass can be repeatedly or continuously determined via at least one travel sensor, and the first derivative over time of the distance function determined in this manner can be numerically formed via the evaluation unit. The speed of the sensor frame determined in this way can be forwarded to a control unit, and actuators can be caused to initiate a counterforce directed against the determined speeds. Furthermore, it is also possible for the evaluation unit to numerically form the second derivative over time of the captured distances. The acceleration of the sensor frame determined in this way can be forwarded to a control unit, and actuators can be caused to initiate a counterforce directed against the determined accelerations. Alternatively, the vibration isolation system may additionally have a viscous damper in order to damp unwanted vibrations of the vibration isolation system. The sensor frame can be suspended from a force frame. Furthermore, it is also possible for the evaluation unit to numerically form the second derivative over time of the captured distances.

Alternatively or additionally, it can be desirable for the measurement object to be a force frame for an optical element of the microlithographic projection exposure apparatus, wherein the force frame is connected to the optical element and at least one actuator connected to the optical element is attached to the force frame for the purpose of adjusting or deforming the optical element.

The disclosure furthermore also relates to a method for operating a sensor device for a microlithographic projection exposure apparatus according to the disclosure, wherein the method comprises the following steps:
a. repeatedly capturing the distance between the measurement object and the auxiliary mass along a first measurement axis via the at least one travel sensor, and
b. forwarding the distances captured by the sensor to an evaluation unit.

The features and embodiments described in connection with the sensor device are also applicable to the method comprising the sensor device.

According to the disclosure, the method can further comprise the following step:
c. forming the first derivative and/or the second derivative of the distances over time.

Furthermore, it can be desirable for the speeds and/or accelerations determined in this way to be forwarded from the evaluation unit to a control unit in order to initiate measures. In the context of the method, it can be desirable for the control unit to cause actuators to initiate counterforces that are proportional to the captured speed/acceleration for the active damping of the measurement object, or in order to eliminate disturbance variables or to adjust the position of the optical elements. The sampling rate of the measurements can be at least 100 Hz, such as at least 1 kHz, for example at least 20 kHz.

In the context of the method, it can be desirable for a second sensor in the form of a travel sensor repeatedly to capture the distance between the measurement object and the auxiliary mass in a second measurement axis that is linearly independent of the first measurement axis, and for a third sensor in the form of a travel sensor repeatedly to capture the distance between the measurement object and the auxiliary mass along a third measurement axis which is linearly independent of the first and the second measurement axis.

In order to also be able to capture movements of the measurement object above 100 Hz with a good signal-to-noise ratio over a wide frequency range, it can be desirable for the captured signals—i.e. movements—which are greater than a predefined or predefinable cutoff frequency or a cutoff frequency range of the travel sensor to be attenuated via a low-pass filter, and for the captured signals-i.e. movements-which are smaller than a predefined or predefinable cutoff frequency or cutoff frequency range of the acceleration sensor to be attenuated via a high-pass filter, wherein the sum of the transfer function of the signals from the travel sensor and the acceleration sensor is approximately 1. In other words, the signals captured by the travel sensor can be used for smaller movements of the measurement object below the cutoff frequency or below the cutoff frequency range, and the measurement signals captured by the acceleration sensor are used for larger movements of the measurement object above the cutoff frequency and above the cutoff frequency range. The larger movements which are captured by the travel sensor and are greater than the cutoff frequency or the cutoff frequency range are damped via the low-pass filter and the smaller movements which are captured by the acceleration sensor and are smaller than the cutoff frequency or the cutoff frequency range can be damped via a high-pass filter.

The features, embodiments and previously described configurations of the sensor device can be applied to the method for operating the sensor device.

Further features, properties and aspects of the present disclosure are described in more detail below on the basis of embodiment variants and with reference to the appended figures. In this respect, all the features described above and below can be combined both individually and in any desired combination. The embodiment variants described below are merely examples which, however, do not limit the subject matter of the disclosure.

### BRIEF DESCRIPTION OF THE DRAWINGS

In the figures:

FIG. 1A shows a schematic illustration of a microlithographic projection exposure apparatus designed for operation in the EUV;

FIG. 1B shows a schematic illustration of a microlithographic projection exposure apparatus designed for operation in the DUV;

FIG. 2 shows a schematic illustration of a first exemplary embodiment of a sensor device;

FIG. 3 shows a schematic illustration of a second exemplary embodiment of a sensor device;

FIG. 4 shows a schematic illustration of a third exemplary embodiment of a sensor device;

FIG. 5 shows a schematic illustration of a fourth exemplary embodiment of a sensor device;

FIG. 6 shows a schematic illustration of a fifth exemplary embodiment of a sensor device; and

FIG. 7 shows a schematic illustration of the signal processing in an exemplary embodiment with both at least one acceleration sensor and a travel sensor.

### DETAILED DESCRIPTION

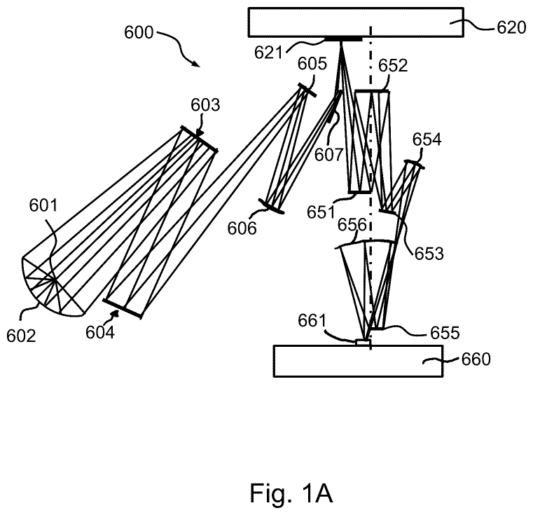

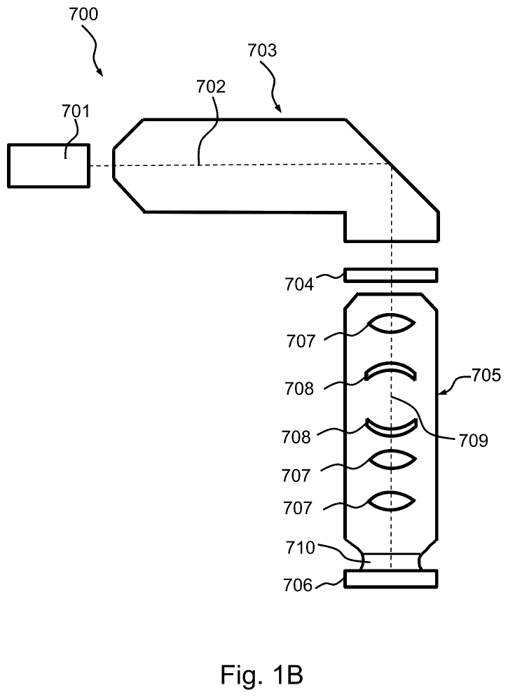

FIG. 1A shows a schematic illustration of an exemplary projection exposure apparatus 600 which is designed for operation in the EUV and in which the present disclosure can be realized.

According to FIG. 1A, an illumination device in a projection exposure apparatus 600 designed for EUV comprises a field facet mirror 603 and a pupil facet mirror 604. The light from a light source unit comprising a plasma light source 601 and a collector mirror 602 is directed to the field facet mirror 603. A first telescope mirror 605 and a second telescope mirror 606 are arranged downstream of the pupil facet mirror 604 in the light path. A deflection mirror 607 is arranged downstream in the light path and directs the radiation that is incident thereon onto an object field in the object plane of a projection lens comprising six mirrors 651-656. At the location of the object field, a reflective structure-bearing mask 621 is arranged on a mask stage 620 and with the aid of the projection lens is imaged into an image plane, in which a substrate 661 coated with a light-sensitive layer (photoresist) is situated on a wafer stage 660. The sensor device according to the disclosure can be used in the projection lens or in an illuminator of an EUV projection exposure apparatus.

The disclosure may likewise be used in a DUV apparatus, as illustrated in FIG. 1B. A DUV apparatus is set up in principle like the above-described EUV apparatus from FIG. 1A, wherein mirrors and lens elements can be used as optical elements in a DUV apparatus and the light source of a DUV apparatus emits used radiation in a wavelength range of 100 nm to 300 nm.

The DUV lithography apparatus 700 illustrated in FIG. 1B comprises a DUV light source 701. For example, an ArF excimer laser that emits radiation 702 in the DUV range at for example 193 nm may be provided as the DUV light source 701. A beam shaping and illumination system 703 guides the DUV radiation 702 onto a photomask 704. The photomask 704 is embodied as a transmissive optical element and may be arranged outside the systems 703. The photomask 704 comprises a structure that is imaged onto a wafer 706 or the like in a reduced fashion via the projection system 705. The projection system 705 comprises multiple lens elements 707 and/or mirrors 708 for imaging the photomask 704 onto the wafer 706. In this case, individual lens elements 707 and/or mirrors 708 of the projection system 705 may be arranged symmetrically with respect to the optical axis 709 of the projection system 705. It should be noted that the number of lens elements 707 and mirrors 708 of the DUV lithography apparatus 700 is not restricted to the number illustrated. A greater or lesser number of lens elements 707 and/or mirrors 708 may also be provided. For example, the beam shaping and illumination system 703 of the DUV lithography apparatus 700 comprises multiple lens elements 707 and/or mirrors 708. Furthermore, the mirrors are generally curved on their front side for beam shaping purposes. An air gap 710 between the last lens element 707 and the wafer 706 can be replaced by a liquid medium having a refractive index of >1. The liquid medium may be high-purity water, for example. Such a construction is also referred to as immersion lithography and has an increased photolithographic resolution.

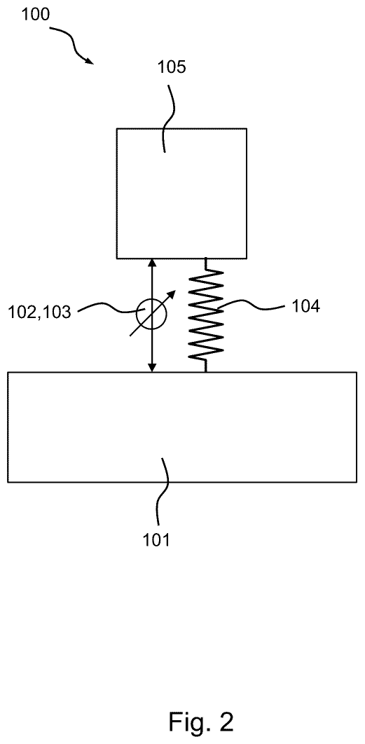

FIG. 2 shows a first exemplary embodiment of a sensor device 100 for a microlithographic projection exposure apparatus 600, 700 or an illumination device, having a measurement object 101, at least one sensor 102 assigned to the measurement object 101 and an evaluation unit which is not illustrated in any more detail and can be in the form of a control unit or an executable program on a microcontroller. In order to achieve a good signal-to-noise ratio when determining the movement of the measurement object 101 even for small movements, for example in the picometre range, the sensor 102 is in the form of a travel sensor 103. An auxiliary mass 105 which is suspended from the measurement object 101 via a resilient element 104 and is thus motionless serves as the reference for the sensor 102.

The sensor 102 is configured to capture the distance between the auxiliary mass 105 and the measurement object 101 along a first measurement axis. For simpler signal processing, the evaluation unit is configured to numerically form the first derivative and/or the second derivative of the distances captured by the travel sensor 103. The first derivative and/or the second derivative of the distances repeatedly captured via the travel sensor 103, i.e. a distance function, is/are optionally numerically formed via the evaluation unit or an additional control unit, e.g. by the difference quotient

$$x ( t ) \approx \frac{\dot{x ( t ) - x} ( t - T )}{T} ,$$

where T is the sampling time. As a result, the speeds and/or accelerations are determined in a similar manner to the values usually captured for the sensors in a microlithographic projection exposure apparatus 800, 700.

So that the auxiliary mass 105 is decoupled from the measurement object 101, the auxiliary mass is suspended from the measurement object 101 via a resilient element 104. The suspension frequency is between 0.1 Hz and 100 Hz, such as between 0.1 Hz and 50 Hz, for example between 1 Hz and 30 Hz. Good decoupling between the measurement object 101 and the auxiliary mass can be achieved via this suspension that is selected to be very soft. The resilient element 104 can be in the form of a leaf spring or a spiral spring. Furthermore, it is also possible for the resilient element 104 to be in the form of a permanent magnetic gravity compensator which is not illustrated in any more detail. Furthermore, the resilient element may also be in the form of a combination of different springs or a combination of at least one spring with a magnetic gravity compensator.

The measurement object 101 may be in the form of an optical element, for example one of the mirrors 603, 604, 605, 606, 607, 651, 652, 653, 654, 655, 656 or lens elements of the projection lens of the projection exposure apparatus 600, 700.

Alternatively or additionally, the measurement object 101 is in the form of a sensor frame which is not illustrated in any more detail and is suspended from a force frame coupled to the optical element, wherein the sensor frame has at least one position sensor for the optical element. The sensor frame is used to check the position of the optical elements via the at least one position sensor. The sensor frame can be decoupled in order to decouple it from the environment, for example from ground vibrations or vibrations caused by the movement of the wafer stage. Via the sensor device and for example by the use of the travel sensors 103, even small movements of the sensor frame, i.e. movements of the sensor frame in the frequency range between 1 Hz and 100 Hz, can be detected with a good signal-to-noise ratio. The speeds determined by forming the first derivative of the captured distances or movement frequencies, or the acceleration determined by forming the second derivative of the captured distances or movement frequencies, can then be forwarded to a control unit in order to take measures, for example to damp the sensor frame to a greater or lesser extent, and to cause actuators to adjust the sensor frame, or to initiate counterforces, etc. The position sensors of the sensor frame can also be in the form of travel sensors, whose signal is differentiated once or twice.

Alternatively or additionally, the measurement object 101 may be in the form of a force frame which is not illustrated in any more detail and is connected to an optical element, wherein at least one actuator is arranged on the force frame on the side facing the optical element. The actuator can be used to adjust the position and/or deform the optically active surface of the optical element. In the present case, it can be desirable for the evaluation unit to be configured to numerically determine the second derivative of the distances captured by the travel sensor.

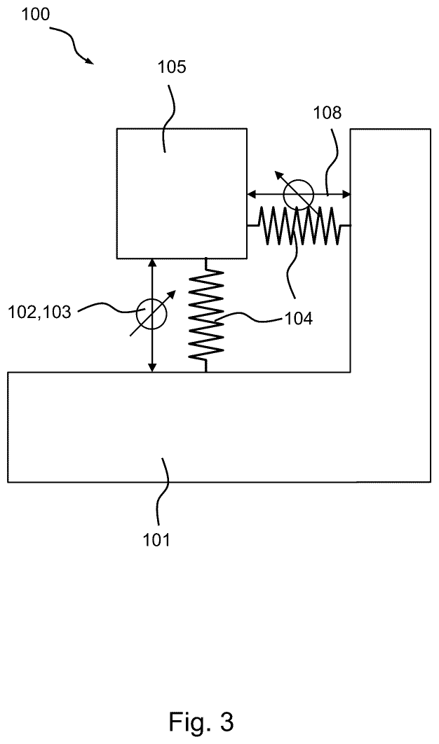

The exemplary embodiment according to FIG. 3 differs in that a second sensor 108 in the form of a travel sensor 103 is present and is configured to capture the distance between the measurement object 101 and the auxiliary mass 105 along a second measurement axis arranged perpendicular to the first measurement axis. In the present case, the auxiliary mass is also decoupled from the measurement object 101 via a resilient element 104 parallel to the second measurement axis. In order to be able to capture a change in movement along all three translational degrees of freedom, a third sensor which is in the form of a travel sensor 103 and is not illustrated in any more detail, may furthermore also be present and is configured to capture the distance between the measurement object 101 and the auxiliary mass 105 along a third measurement axis arranged perpendicular to the first measurement axis and the second measurement axis. The auxiliary mass 105 can then be decoupled from the measurement object 101 along this measurement axis via a resilient element 104 which is not illustrated in any more detail and is arranged parallel to the third measurement axis or acts parallel to the third measurement axis.

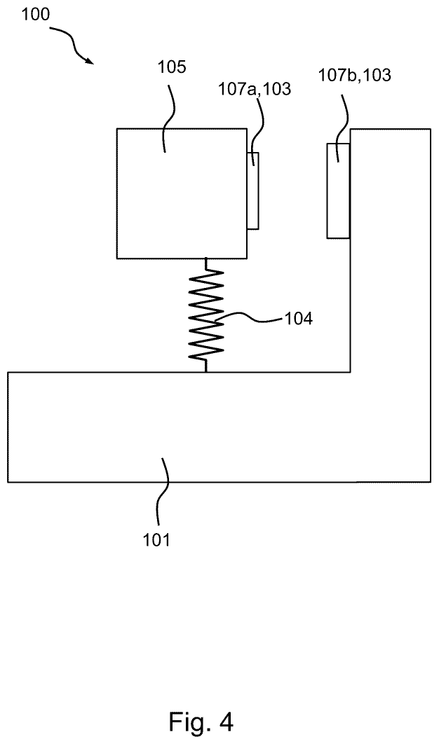

In the exemplary embodiment according to FIG. 4, the travel sensor 103 is in the form of an optical encoder 107 which comprises a scale 107a arranged on the auxiliary mass and an optics unit 107b which is arranged on the measurement object opposite the scale 107a and has a light source and at least one grating. Alternatively, the travel sensor may also be in the form of an interferometer or a capacitive sensor.

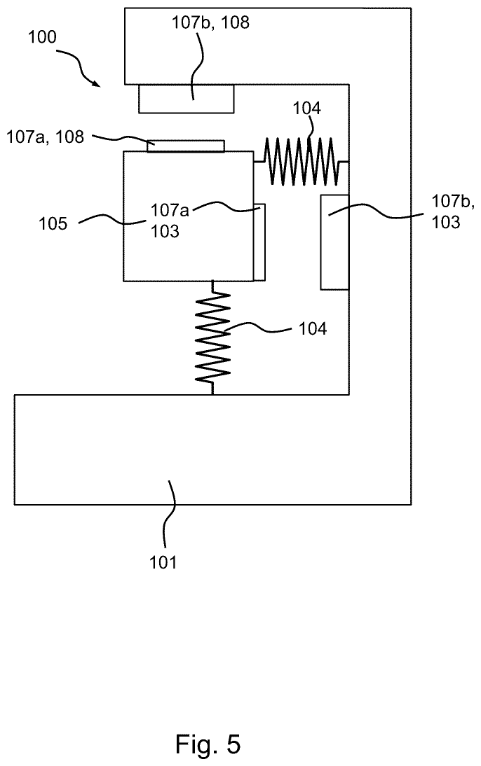

The exemplary embodiment according to FIG. 5 differs from that according to FIG. 4 in that two optical encoders 107 are provided, wherein the one optical encoder 107 measures along a first measurement axis and the second optical encoder measures along a second measurement axis arranged perpendicular to the first measurement axis.

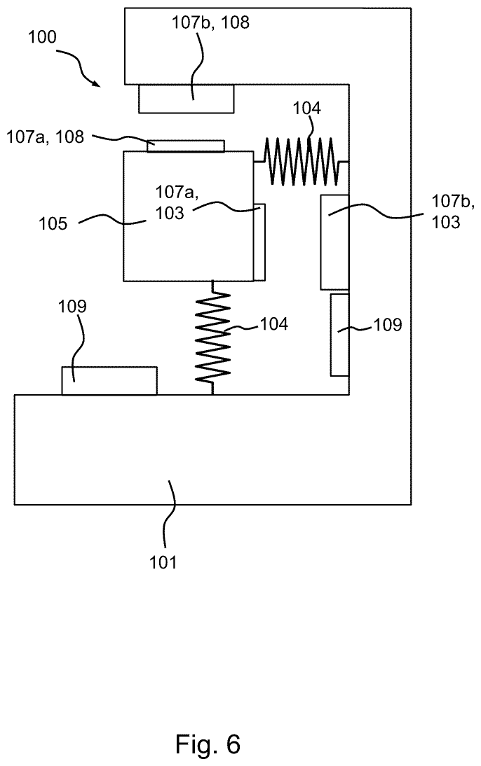

The exemplary embodiment according to FIG. 6 differs in that, in addition to the travel sensors 103, acceleration sensors 109 are present. A low-pass filter is assigned to the travel sensor 103. This damps signal frequencies of the travel sensor 103 above a predefined cutoff frequency or a cutoff frequency range. In other words, larger movements or higher frequencies, which are better captured via an acceleration sensor 109, are damped and only those signal frequencies/movements which are in a frequency range of for example less than 100 Hz are captured via the travel sensor. Conversely, a high-pass filter is assigned to the acceleration sensors 109. This makes it possible to damp the measured signal frequencies/movements below a predefined cutoff frequency or a cutoff frequency range. The filters are selected in such a way that the sum of the transfer function of the signals from the acceleration sensor 109 and the travel sensor 103 is approximately 1.

The method for operating a sensor device 100 for a microlithographic projection exposure apparatus 600, 700 comprises the following steps: First, the distance between a measurement object 101 and an auxiliary mass 105 is repeatedly captured along a first measurement axis via at least one travel sensor 103. Analogously, but optionally, a second sensor 108 in the form of a travel sensor 103 can also repeatedly capture the distance between the measurement object 101 and the auxiliary mass 105 along a second measurement axis perpendicular to the first measurement axis and/or a third sensor in the form of a travel sensor 103 can repeatedly capture the distance between the measurement object 101 and the auxiliary mass 105 along a third measurement axis perpendicular to the first and the second measurement axis.

A distance function is formed by repeatedly capturing the distances. An evaluation unit is used to numerically determine the first derivative, i.e. the speed of the measurement object, and/or the second derivative, i.e. the acceleration, over time. The evaluation unit can also be in the form of a control unit, or a microcontroller. The control unit or an additional control unit can then take measures depending on the speed values or acceleration values determined. For example, the control unit can cause actuators to adjust a position of an optical element or a deformation of an active surface of an optical element. It is also possible for the control unit to cause a parameter change of a vibration isolation system of a sensor frame. When detecting vibrations, the orientation or deformation of the optical element can also be adjusted via the control unit in order to reduce the aberrations caused by vibrations or other disturbance variables.

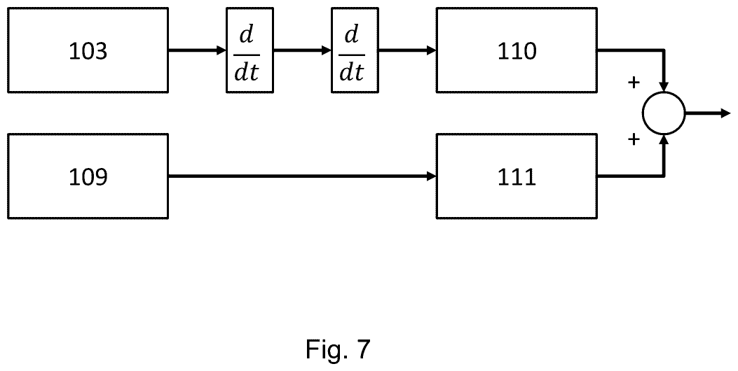

FIG. 7 schematically illustrates a sequence of signal processing if the sensor device 100, in addition to the at least one travel sensor 103, also additionally comprises at least one acceleration sensor 109. The captured signals from the at least one travel sensor 103, that is to say the once or twice derived distances, which are greater than a predefined or predefinable cutoff frequency or a cutoff frequency range, are attenuated via a low-pass filter 110. Conversely, the signals which are captured via the acceleration sensor 109 and are smaller than a predefined or predefinable cutoff frequency or a cutoff frequency range are attenuated via a high-pass filter 111, wherein the sum of the transfer function of the signals from the travel sensor 103 and the acceleration sensor 109 is approximately 1. In other words, the small movements below optionally 50 Hz to 500, such as 70 Hz to 300 Hz, for example 100 Hz to 200 Hz, are read/detected via the travel sensor 103, while the larger movements above this cutoff frequency or this cutoff frequency range are read/detected via acceleration sensors 109. This enables larger movements as well as smaller movements in the picometre range or larger accelerations and smaller accelerations in the mm/s2 range of a measurement object 101 to be detected with an optimal signal-to-noise ratio.

### LIST OF REFERENCE SIGNS

100 Sensor device
101 Measurement object
102 Sensor
103 Travel sensor
104 Resilient element
105 Auxiliary mass
107 Encoder
107a Scale (encoder)
107b Optics unit (encoder)
108 Second sensor
109 Acceleration sensor
110 Low-pass filter
111 High-pass filter
600 Projection exposure apparatus
601 Plasma light source
602 Collector mirror
603 Field facet mirror
604 Pupil facet mirror
605 First telescope mirror
606 Second telescope mirror
607 Deflection mirror
620 Mask stage
621 Mask
651 Mirror (projection lens)
652 Mirror (projection lens)
653 Mirror (projection lens)
654 Mirror (projection lens)
655 Mirror (projection lens)
656 Mirror (projection lens)
660 Wafer stage
661 Coated substrate
700 DUV lithography apparatus
701 DUV light source
702 DUV radiation/beam path
703 Beam shaping and illumination system (DUV)
704 Photomask
705 Projection system
706 Wafer
707 Lens element
708 Mirror
709 Optical axis

What is claimed is:

1. A sensor device, comprising:
a measurement object;
a travel sensor;
a resilient element;
an auxiliary mass suspended from the measurement object via the resilient element so that the auxiliary mass is a reference for the travel sensor; and
an evaluation unit,
wherein:
the travel sensor is configured to capture a distance between the auxiliary mass and the measurement object along a first measurement axis; and
the evaluation unit is configured to numerically form a first derivative and/or a second derivative of distances captured by the travel sensor.

2. The sensor device of claim 1, wherein the travel sensor comprises an optical encoder.

3. The sensor device of claim 1, wherein the travel sensor comprises a capacitive sensor or an interferometer.

4. The sensor device of claim 1, wherein the resilient element has a suspension frequency between 0.1 Hz and 100 Hz.

5. The sensor device of claim 1, further comprising a second travel sensor, wherein the second travel sensor is configured to capture a distance between the measurement object and the auxiliary mass in a second measurement axis which is linearly independent with respect to the first measurement axis.

6. The sensor device of claim 5, further comprising a third travel sensor, wherein the third travel sensor is configured to capture a distance between the measurement object and the auxiliary mass in a third measurement axis which is linearly independent with respect to the first measurement axis and the second measurement axis.

7. The sensor device of claim 1, wherein the resilient element comprises a leaf spring or a spiral spring.

8. The sensor device of claim 1, wherein the resilient element comprises a magnetic gravity compensator.

9. The sensor device of claim 1, further comprising an acceleration sensor configured to capture an acceleration of the measurement object along the first measurement axis.

10. The sensor device of claim 9, further comprising:
a low-pass filter assigned to the travel sensor to attenuate the captured signal from the travel sensor above a cutoff frequency or above a cutoff frequency range; and
a high-pass filter assigned to the acceleration sensor to attenuate the captured signal below a cutoff frequency or a cutoff frequency range,
wherein a sum of a transfer function of signals from the acceleration sensor and the travel sensor is approximately one.

11. The sensor device of claim 1, wherein the measurement object comprises an optical element.

12. The sensor device of claim 1, wherein the measurement object comprises a sensor frame suspended from an optical element, and the sensor frame comprises a position sensor for an optical element.

13. The sensor device of claim 1, further comprising an actuator, wherein the measurement object comprises a force frame which connected to an optical element, and the actuator is on a side of the force frame facing the optical element.

14. The sensor device of claim 1, wherein:
the travel sensor comprises an optical encoder, a capacitive sensor or an interferometer;
the resilient element has a suspension frequency between 0.1 Hz and 100 Hz;
the resilient element comprises a leaf spring, a spiral spring or a magnetic gravity compensator; and
the measurement object comprises an optical element, or the measurement object comprises a sensor frame suspended from an optical element, and the sensor frame comprises a position sensor for an optical element.

15. The sensor device of claim 14, further comprising a second travel sensor, wherein the second travel sensor is configured to capture a distance between the measurement object and the auxiliary mass in a second measurement axis which is linearly independent with respect to the first measurement axis.

16. The sensor device of claim 15, further comprising an acceleration sensor configured to capture an acceleration of the measurement object along the first measurement axis.

17. An apparatus, comprising:
a sensor device according to claim 1,
wherein the apparatus is a microlithographic projection exposure apparatus.

18. A method, comprising:
providing a sensor device according to claim 1;
repeatedly capturing the distance between the measurement object and the auxiliary mass along the first measurement axis using the travel sensor;
forwarding the distances captured by the sensor to the evaluation unit; and
using the evaluation unit to form the first derivative and/or the second derivative of the distances over time.

19. The method of claim 18, further comprising:
using a second travel sensor of the sensor device to repeatedly capture a distance between the measurement object and the auxiliary mass along a second measurement axis that is linearly independent of the first measurement axis; and
using a third travel sensor of the sensor device to repeatedly capture a distance between the measurement object and the auxiliary mass along a third measurement axis which is linearly independent of the first and the second measurement axis.

20. The method of claim 18, further comprising:
using a low-pass filter to attenuate captured signals which are greater than a cutoff frequency or a cutoff frequency range of the travel sensor via a low-pass filter; and
using a high-pass filter to attenuate captured signals which are less than a cutoff frequency or cutoff frequency range of an acceleration sensor of the sensor device,
wherein a sum of a transfer function of signals from the travel sensor and the acceleration sensor is approximately one.
